(19) United States
(12) Patent Application Publication
(10) Pub. No.: US 2026/0317160 A1
(43) Pub. Date: Oct. 15, 2026

(54) MICROELECTROMECHANICAL SENSOR COMPONENT, MICROELECTROMECHANICAL INERTIAL SENSOR, AND METHOD FOR PRODUCING A MICROELECTROMECHANICAL SENSOR COMPONENT

(71) Applicant: Robert Bosch GmbH, Stuttgart (DE)

(72) Inventors: Jochen Reinmuth, Reutlingen (DE); Andrea Urban, Stuttgart (DE); Andreas Lassl, Korntal-Muenchingen (DE); Jana Ochs, Reichenau (DE); Marian Hoersting, Emsdetten (DE); Matthias Kuehnel, Boeblingen (DE); Matthias Wenzel, Marbach Am Neckar (DE); Matthias Senge, Olsberg (DE); Thorsten Balslink, Kirchentellinsfurt (DE)

(21) Appl. No.: 19/321,500

(22) Filed: Sep. 8, 2025

(30) Foreign Application Priority Data
Sep. 24, 2024 (DE) 10 2024 209 168.5

(51) Int. Cl. B81B 3/00; B81C 1/00

(52) U.S. Cl. CPC B81B 3/0094; B81C 1/00714; B81B 2201/0235; B81B 2203/0136; B81B 2203/04; B81C 2201/0105; B81C 2201/0132; B81C 2201/014

(57) ABSTRACT

A microelectromechanical sensor component. The microelectromechanical sensor component includes: a substrate with a substrate surface, a deflection electrode which is movable substantially perpendicularly to the substrate surface, and an evaluation electrode for capacitively detecting a deflection of the deflection electrode. The evaluation electrode has a vertical evaluation electrode surface which is aligned substantially perpendicularly to the substrate surface and runs at least in portions parallel to a vertical deflection electrode surface of the deflection electrode while forming a vertical electrode gap between the vertical deflection electrode surface and the vertical evaluation electrode surface. A microelectromechanical inertial sensor including such a microelectromechanical sensor component, and a method for producing such a microelectromechanical sensor component, are also described.

### FIELD

The present invention relates to a microelectromechanical sensor component and a microelectromechanical inertial sensor comprising such a microelectromechanical sensor component. The present invention also relates to a method for producing such a microelectromechanical sensor component.

### BACKGROUND INFORMATION

Certain microelectromechanical devices and sensor components as well as methods for their production are described in the related art.

Germany Patent Application No. DE 195 37 814 A1 describes a sensor, in particular an acceleration sensor, with a substrate and a silicon layer. A movable element is structured out of the silicon layer, the movable element being connected to the substrate. Between the substrate and the silicon layer, a conductive layer is provided, which is isolated from part of the silicon layer by an isolation layer. Furthermore, a method for producing such a sensor is disclosed.

Microelectromechanical sensor components may, inter alia due to their microstructural characteristics, exhibit a high sensitivity to environmental influences, to which they can react with mechanical bending effects, as is the case, for example, with different thermal expansion coefficients of carrier materials and sensor materials. In addition, microelectromechanical sensor components are usually produced by a layer-by-layer construction of functional structures on or in a substrate, stress effects of the layer structure possibly causing further mechanical bending effects in the substrate and/or in the functional layers.

Mechanical bending effects represent a technical challenge in the field of microelectromechanical sensor components in particular when the sensor component is designed to detect so-called out-of-plane deflections of a movable sensor structure perpendicularly to a substrate surface, and the measurement principle of the sensor component is based, for example, on the detection of changes in distance between the movable sensor structure and an immobile reference structure. In this case, the mechanical bending effects can lead to deflection-independent distance changes, which can be compensated with regard to the measurement signals to be evaluated, for example, by differential measurement concepts but may sometimes lead to design limitations and to changing measurement sensitivities of the sensor components. If, for example, a layer stress in the sensor component causes a bending of the substrate or of the movable sensor structure the extent of which exceeds a distance between the substrate or a reference structure arranged thereon and the movable sensor structure, this can lead to an impairment of the function of the sensor component.

Accordingly, the design of the sensor component must be adapted to the expected layer stress, resulting in a design limitation with regard to the size of the movable sensor structure of the sensor component and with regard to its distance from the reference structure. However, a large movable sensor structure and a short distance to the reference structure, for example to a fixed electrode, can promote a pronounced measurement signal, in particular in the case of capacitive measurement principles, and thus increase the measurement accuracy. Furthermore, for sensor components in which a deflection of the movable sensor structure can be detected by a change in capacitance between the movable sensor structure and a fixed counter electrode, a change in distance due to bending effects can lead to a change in sensor sensitivity since the capacitance is fundamentally inversely proportional to the distance between the movable sensor structure and the fixed counter electrode. In this case, a change in sensor sensitivity cannot be compensated in comparison to an obtainable capacitive measurement signal which can be adjusted to a basic capacitance, for example by differential measurement.

### SUMMARY

According to an example embodiment of the present invention, a microelectromechanical sensor component is provided which comprises a substrate with a substrate surface, a deflection electrode movable substantially perpendicularly to the substrate surface, and an evaluation electrode for capacitively detecting a deflection of the deflection electrode, the evaluation electrode having a vertical evaluation electrode surface which is aligned substantially perpendicularly to the substrate surface and extends at least in portions parallel to a vertical deflection electrode surface of the deflection electrode while forming a vertical electrode gap between the vertical deflection electrode surface and the vertical evaluation electrode surface.

In other words, in simplified terms, it is provided to use a variable overlap of vertical electrode surfaces for capacitive deflection detection, instead of detecting changes in distance between horizontal electrode surfaces extending parallel to the substrate surface. Such a detection approach offers multiple advantages over conventional measurement principles with horizontally extending electrode surfaces for detecting out-of-plane deflections. For example, the detection arrangement with vertical electrode surfaces according to the present invention, which is referred to below as vertical detection arrangement for reasons of simplicity, has a consistent sensitivity even if bending effects in the sensor component cause a vertical change in the distance between the deflection electrode and the evaluation electrode. The sensor component is therefore capable of providing consistently sensitive measurement signals, regardless of mechanical stress effects and thermal influences.

In other words, regardless of any existing pre-deflection of the evaluation or deflection electrode, the same capacitance change can always be expected with the same deflection of the deflection electrode. In addition, a linear measurement signal is provided by a variable overlap of the vertical electrode surfaces, representing the deflection of the deflection electrode, since the capacitance change correlating with the change in overlap depends directly proportionally on the deflection. In this case, the capacitance increases linearly with increasing overlap and decreases linearly with decreasing overlap of the vertical electrode surfaces. Furthermore, mechanical stress and bending effects can largely be ignored when designing the sensor structure with regard to measurement accuracy. For example, a movable sensor structure of any size, which can comprise the deflection electrode and optionally a seismic mass connected to the deflection electrode as a mechanical inertia element, and a particularly narrow vertical electrode gap can be formed in the sensor component. Such a design allows for distinct and precise measurement signals to be obtained. In this case, a maximum possible capacitive signal is no longer limited by layer properties of the corresponding functional layers, since the vertical detection arrangement is substantially insensitive to mechanical layer stress. As a result, a microelectromechanical sensor component can be provided which can detect an out-of-plane displacement of the deflection electrode without showing a change in the sensitivity of the measurement signal upon bending of the substrate, and which can also provide a sensitive signal upon bending of the movable sensor structure.

According to an example embodiment of the present invention, a microelectromechanical sensor component can, for example, be a component that is produced with semiconductor technology and has mechanical and electrical microstructures. A microelectromechanical sensor component can be suitable for implementation as a system-on-chip (SoC) due to its microstructural design. As a sensor component, the microelectromechanical sensor component can, for example, be configured to detect physical quantities. The sensor component described in the context of this application can be configured in particular for the direction-dependent detection of an acceleration or rotation rate, which are referred to below collectively as acceleration in the sense of a translational or rotational acceleration.

According to an example embodiment of the present invention, the substrate can be a flat semiconductor carrier structure. The substrate can be a silicon wafer, for example. The substrate has two mutually opposite substrate surfaces that can be referred to as a front side and a rear side. The front side of the substrate can form an active side of the substrate, on which side the mechanical and electrical microstructures of the sensor component are arranged. If an extension perpendicular to a substrate surface is mentioned here, this can refer to the substrate surface on the front side of the substrate. In this case, a substantially perpendicular extension to the substrate surface can be understood, for example, in such a way that a main axis of the component in question runs at a right angle to the substrate surface with a maximum deviation of, for example, 10% or 5%. A substantially perpendicular mobility relative to the substrate surface may include movement paths with a predominant directional component transverse to the substrate surface. Extensions and spatial directions running substantially perpendicularly to the substrate surface are referred to herein as vertical, while extensions and spatial directions parallel to the substrate surface represent horizontal alignments.

According to an example embodiment of the present invention, the deflection electrode and the evaluation electrode can be electrically conductive electrode elements that are arranged in the sensor component so as to be movable relative to one another. The evaluation electrode can be arranged at least in portions between the substrate and the deflection electrode. In particular, the evaluation electrode can be fixedly anchored to the substrate, while the deflection electrode is arranged to be movable relative to the evaluation electrode. For example, as explained in more detail below, the deflection electrode can be attached to a movable seismic mass of the sensor component. When subjected to an acceleration, the deflection electrode can be transferred from a defined rest position into a capacitively detectable deflection position so that the detected relative deflection with respect to the rest position can be a measure of the applied acceleration. The evaluation electrode is configured to capacitively detect a deflection of the deflection electrode through electrostatic interaction with the deflection electrode. In addition to its mechanical connection to the substrate, the evaluation electrode can have an electrical connection to a conductor track arranged on the substrate for example, in order to make tapping of the capacitive measurement signal of the evaluation electrode in interaction with the deflection electrode possible.

According to the provided features of the present invention, the evaluation electrode has a vertical evaluation electrode surface which runs at least in portions parallel to a vertical deflection electrode surface of the deflection electrode while forming a vertical electrode gap between the vertical deflection electrode surface and the vertical evaluation electrode surface. The vertical evaluation electrode surface and the vertical deflection electrode surface can therefore be arranged at least partially opposite one another, a free space or intermediate space between the opposing surface portions of the vertical deflection electrode surface and the vertical evaluation electrode surface being referred to as an electrode gap. In an undeflected rest position of the deflection electrode, the vertical evaluation electrode surface and the vertical deflection electrode surface can have a vertical offset in the sense of a partially overlapping arrangement. For example, the vertical evaluation electrode surface may protrude further in the direction of the substrate surface than the vertical deflection electrode surface, and/or the vertical deflection electrode surface may protrude further in an opposite direction away from the substrate surface than the vertical evaluation electrode surface.

According to one example embodiment of the present invention, the evaluation electrode may have an evaluation electrode bar which extends substantially perpendicularly to the substrate surface and on which the vertical evaluation electrode surface is formed. Alternatively or additionally, the deflection electrode may comprise a deflection electrode bar which extends predominantly perpendicularly to the substrate surface and on which the vertical deflection electrode surface is formed. With such evaluation electrode bars and/or deflection electrode bars, a defined detection structure with vertical electrode surfaces can be provided, which allows for precise and consistently sensitive capacitive deflection detection. In particular, an evaluation electrode bar can have at least two mutually opposing vertical evaluation electrode surfaces, each of which runs at least partially parallel to a vertical deflection electrode surface, and/or the deflection electrode bar can have at least two mutually opposing vertical deflection electrode surfaces, each of which runs at least partially parallel to a vertical evaluation electrode surface, so that a stronger capacitive measurement signal is obtainable due to the increased total electrode surface available for deflection detection. An evaluation electrode bar can be understood as a vertical electrode portion of the evaluation electrode, which, for example, is block-shaped or elongate and, in a narrow embodiment with a significantly greater length than width, can also be referred to as an evaluation electrode finger. A deflection electrode bar can be understood analogously as a vertical electrode portion of the deflection electrode, which, for example, is block-shaped or elongate and, in a narrow embodiment with a significantly greater length than width, can also be referred to as a deflection electrode finger.

According to one example embodiment of the present invention, the sensor component may comprise a plurality of evaluation electrode bars and a plurality of deflection electrode bars that interlock vertically in a comb-like manner. This allows for the provision of a vertical comb structure, which makes reliable and precise deflection detection with a distinct measurement signal possible. Such a vertical comb structure can, for example, have at least two evaluation electrode bars and at least two deflection electrode bars, which are arranged alternately next to one another while forming respective electrode gaps between the vertical electrode surfaces running parallel to one another at least in portions. In other words, the deflection electrode bars are immersed into the intermediate spaces between the evaluation electrode bars, and the evaluation electrode bars are immersed into the intermediate spaces between the deflection electrode bars. Due to the relative mobility of the deflection electrode, the engagement of the evaluation electrode bars in the intermediate spaces between the deflection electrode bars and the engagement of the deflection electrode bars in the intermediate spaces between the evaluation electrode bars can increase or decrease during a deflection so that the respective electrode bars can be immersed further or less far into the intermediate spaces. In this case, for example in comparison to comb structures used as electrostatic drives in actuator components, small immersion depths for the sensor component are already sufficient to make reliable deflection detection possible. For example, an immersion depth or, in other words, an overlap length, of a deflection electrode bar and an adjacent evaluation electrode bar in a rest position of the deflection electrode can be between 0.5 and 1.5 um according to a non-limiting numerical example.

In principle, different geometric design options for the evaluation electrode bars and deflection electrode bars are possible. For example, these electrode bars can be designed as narrow electrode fingers or as wide electrode blocks and can be combined in a variety of ways. For example, it is possible that the deflection electrode bars are designed as narrow deflection electrode fingers and the evaluation electrode bars are designed as narrow evaluation electrode fingers. Alternatively, the deflection electrode bars can be designed as wide deflection electrode blocks and the evaluation electrode bars can be designed as wide evaluation electrode blocks. Furthermore, the deflection electrode bars can be designed as narrow deflection electrode fingers and can be immersed into the intermediate spaces between wide evaluation electrode blocks. Furthermore, the evaluation electrode bars can be designed as narrow evaluation electrode fingers and can be immersed into the intermediate spaces between wide deflection electrode blocks. For example, an electrode finger can be at most ten times as wide as the electrode gap between an electrode surface of the electrode finger and an adjacent electrode surface. For example, an electrode block can be at least ten times as wide as the electrode gap between an electrode surface of the electrode finger and an adjacent electrode surface. Wide electrode blocks can be associated with easier production and greater robustness of the sensor component, while narrow electrode fingers allow a higher number of electrode bars and thus can provide a stronger measurement signal due to the increased total available electrode surface area.

According to one example embodiment of the present invention, the sensor component may comprise a seismic mass with a mass surface facing the substrate, on which surface the deflection electrode is arranged. The seismic mass can form a mechanical inertial body of the sensor component with an increased deflection effect when an external acceleration acts on the sensor component. The seismic mass can, for example, be movably connected to a fixed frame of the sensor component via a spring structure. Depending on the type of acceleration to be detected and the measurement principle used, the seismic mass can, for example, be designed as a rocker structure with rocker arms that have an asymmetric mass distribution and are pivotable about a torsion spring axis; it can be designed as a trampoline structure with a translational displaceability of the entire seismic mass, or it can be configured as an oscillating rotor for rotation rate detection. By arranging the deflection electrode on the mass surface of the seismic mass, the effective mechanical mass of the seismic mass can be further increased. In particular, it is not necessary for the deflection electrode, in particular any vertical deflection electrode bars of the deflection electrode, to protrude from an electrically conductive seismic mass, but rather the mechanical function of the seismic mass and the electrostatic function of the deflection electrode with respect to a capacitive detection of the relative movement between the deflection electrode and the evaluation electrode can be structurally separated from each other and individually optimized. In this case, the deflection electrode is arranged on a side of the seismic mass facing the substrate, i.e., in a top view of the seismic mass, it is located below said seismic mass and can interact electrostatically with an evaluation electrode anchored to the substrate.

According to one example embodiment of the present invention, an extension of the vertical electrode gap between the deflection electrode surface and the evaluation electrode surface can be at most half as large as a distance between the substrate surface and the deflection electrode in a rest position of the deflection electrode. In this case, the distance between the substrate surface and the deflection electrode refers in particular to a distance between the substrate surface and an electrode surface of the deflection electrode running parallel to the substrate surface and facing the substrate surface. The electrode surface can, for example, be an end face of a deflection electrode bar facing the substrate surface. The correspondingly narrow design of the vertical electrode gap compared to a horizontal gap between the substrate and the deflection electrode makes very precise capacitive deflection detection possible. In particular, the extension of the vertical electrode gap between the deflection electrode surface and the evaluation electrode surface can be at most 25% or at most 15% of a distance between the substrate surface and the deflection electrode, whereby a particularly narrow vertical electrode gap can be used for deflection detection. Alternatively or in addition to the described embodiment, it is possible that an extension of the vertical electrode gap between the deflection electrode surface and the evaluation electrode surface corresponds to at most one half or one quarter of the width of a deflection electrode bar having the deflection electrode surface, parallel to the substrate surface, or that an extension of the vertical electrode gap between the deflection electrode surface and the evaluation electrode surface corresponds to at most one half or one quarter of the width of an evaluation electrode bar having the evaluation electrode surface, parallel to the substrate surface. This makes it possible to provide a robust, yet sensitive detection arrangement. According to a non-limiting numerical example, the extension of the vertical electrode gap between the deflection electrode surface and the evaluation electrode surface can be between 100 nm and 1 μm, whereby a high signal quality with a pronounced capacitive measurement signal can be achieved.

According to one example embodiment of the present invention, the vertical evaluation electrode surface and/or the vertical deflection electrode surface can be predominantly flat. This makes it possible to obtain an accurate linear capacitive measurement signal, in particular over the entire maximum possible displacement path of the deflection electrode, without signal fluctuations. A predominantly flat evaluation electrode surface or deflection electrode surface can be understood as a surface of the particular electrode of which at least 75% lies in a continuous flat plane. In particular, the vertical evaluation electrode surface and/or the vertical deflection electrode surface can be completely flat, i.e., have a planar surface along the entire electrode surface. In particular, a predominantly flat design of the vertical evaluation electrode surface and/or the vertical deflection electrode surface can mean that there are no shoulders, steps or projections on the deflection electrode surface and/or the evaluation electrode surface. A suitable production process for forming such flat vertical electrode surfaces is described in more detail below.

The present invention also relates to a microelectromechanical inertial sensor having a microelectromechanical sensor component according to one of the above-described features and having a signal processing unit for applying and/or processing signals of the microelectromechanical sensor component. The inertial sensor can be designed, for example, as an acceleration sensor for detecting a translational acceleration, and/or as a rotation rate sensor for detecting a rotational acceleration, and can have one or more microelectromechanical sensor components, of which at least one microelectromechanical sensor component is designed according to one of the features described above. The inertial sensor can in particular comprise a microelectromechanical sensor component with a seismic mass, to which the deflection electrode is attached. The functional principle of microelectromechanical inertial sensors is based, due to their microstructure, on very small mechanical deflections of the seismic mass that can be detected capacitively but are associated with correspondingly weak measurement signals. Due to the vertical detection arrangement proposed in connection with the microelectromechanical sensor component, with a vertical deflection electrode surface, a vertical evaluation electrode surface and a vertical electrode gap, very narrow electrode gaps and extended functional layers can be formed as a seismic mass in the sensor component, regardless of design limitations due to layer stress or thermal expansion effects, so that stronger measurement signals with a high signal quality can be achieved. At the same time, the proposed design provides a robust inertial sensor with consistent sensitivity. In particular for rotation rate sensors where a high sensitivity drift is usually present and can impair the obtainable measurements, the proposed microelectromechanical sensor component according to the present invention can achieve improved signal quality with very accurate measurement results due to the pre-deflection-independent sensitivity of the vertical detection arrangement. This can be advantageous for certain applications where very precise detection of rotational or translational accelerations is required, for example in the field of vehicle acceleration sensors for vehicle safety functions or in localization applications in personal mobile devices.

The signal processing unit of the inertial sensor can be understood as a control circuit, which can be designed in particular as an integrated circuit, for example as an ASIC (application-specific integrated circuit). The signal processing unit is configured to apply and/or process signals of the microelectromechanical sensor component and can, for example, be used to receive and evaluate sensor signals of the microelectromechanical sensor component and to perform control tasks.

In principle, the proposed microelectromechanical sensor component according to the present invention is also suitable for alternative applications beyond acceleration measurements, for example as an environmental sensor, and is associated with the aforementioned advantages. For example, it is also possible that the proposed microelectromechanical sensor component is implemented in a pressure sensor and the deflection electrode is displaced toward or away from the evaluation electrode depending on an ambient pressure, which can be detected reliably and with consistent sensitivity via the vertical detection arrangement.

The present invention also relates to a method for producing a microelectromechanical sensor component according to one of the features described above by sequential arrangement and layer-by-layer optional structuring of functional material layers and auxiliary material layers, a course of the vertical evaluation electrode surface, the vertical deflection electrode surface and the vertical electrode gap being predefined by auxiliary material layer edges.

According to an example embodiment of the present invention, it can thus be provided that the microelectromechanical sensor component is produced in a layer structure, for example by means of semiconductor processes which can be based on the successive deposition of material layers and the selective removal of layer regions. In this case, the applied material layers are differentiated here into functional material layers and auxiliary material layers, it being possible for functional material layers to form functional layers remaining in the sensor component after the production process and for auxiliary material layers to form auxiliary layers temporarily used during the production process to structure the sensor component. The functional material layers and auxiliary material layers can in particular be applied successively to a substrate, for example a silicon wafer. A functional material layer can be formed, for example, by a ceramic, metal or, in particular, semiconductor-based material layer, which can be formed, for example, as a monocrystalline or polycrystalline silicon layer or also as a dielectric layer made of silicon compounds, such as silicon nitride. Functional material layers can be used, for example, to form the evaluation electrode, the deflection electrode, a seismic mass or mechanical anchors on the sensor component, for example in the form of spring structures or substrate anchors. An auxiliary material layer can, for example, be formed as a so-called sacrificial layer, which is, for example, initially buried in the sensor component, i.e., arranged between functional material layers, and can be at least partially removed again in a subsequent etching process via previously created etching accesses. For example, using sacrificial layers, free spaces can be formed in the sensor component, sacrificial layer regions that have not been removed being usable as needed in a targeted manner as dielectric isolation regions and thus being able to form a local functional material layer region. Materials for sacrificial layers can be selected in particular according to their selective etchability compared to the materials used for the functional material layers. A sacrificial layer can, for example, be a dielectric layer made of a silicon compound such as silicon dioxide. An auxiliary material layer can also be formed as a photoresist layer, which can be applied as a resist mask to an underlying material layer in order to structure it in certain regions. In this case, a resist layer edge can define a vertical boundary of the region of the underlying material layer to be removed. Suitable photoresists can be photosensitive polymers, such as those used in photolithographic structuring processes. The photoresist layer can be applied, for example, in liquid form or as a dry film resist.

The etching processes mentioned in connection with the production of the microelectromechanical sensor component can advantageously be carried out, in particular, with respect to the removal of auxiliary material layers, using dry etching methods, such as plasma etching. In principle, however, wet-chemical etching methods can also be used. For the region-by-region removal of functional material layers, a trench etching method can in particular be used, which makes it possible to remove polysilicon material selectively to silicon dioxide material, for example. Furthermore, the sensor component can be processed in further optional production steps using other processing methods, for example thinned and/or chemically-mechanically polished using a grinding process.

By predefining a course of the vertical evaluation electrode surface, the vertical deflection electrode surface and the electrode gap by auxiliary material layer edges according to the proposed method for producing the microelectromechanical sensor component according to the present invention, it is possible to produce straight and even electrode surfaces in a vertical plane of the sensor component, which promote precise capacitive measurements with a linear output signal. Compared to conventional production steps for the creation of vertical structures, which can be based, for example, on the stacking of functional layer blocks by means of contact points, predominantly step-free, flat vertical surfaces can be created by the geometries predefined by means of the auxiliary material layer edges. The auxiliary material layer edges can be aligned with one another with high precision and make a controlled etching medium distribution along the auxiliary material layer edges possible so that a defined narrow electrode gap can be formed between flat vertical electrode surfaces. In particular, it is not necessary to implement multiple etching process steps to form the vertical detection arrangement, but rather said detection arrangement can be created by the geometry of the vertical detection arrangement, predefined by means of the auxiliary material layer edges, by means of a continuous etching process. In addition, the produced vertical electrode gaps have the advantage that they basically act as etching channels in the component structure of the sensor component to be produced, and can promote the etching gas distribution through the layer structure. This allows for a reduction in the number of etching channels specifically introduced into the functional material layers of the sensor component for the removal of auxiliary material layers.

According to one example embodiment of the present invention, the evaluation electrode and the deflection electrode of the sensor component can be produced by means of a first functional material layer. The first functional material layer can, for example, be a polysilicon layer. For example, a desired electrical conductivity of the first functional layer can be achieved by suitable doping of the polysilicon layer. The first functional material layer can, for example, be arranged on a first sacrificial layer, which in turn is arranged on the substrate, so that an isolating spacing can be achieved between the substrate and the evaluation electrode as well as the deflection electrode. The evaluation electrode can also be attached to the substrate and/or connected to an electrical conductor track via at least one local anchoring structure or carrier structure. The evaluation electrode and the deflection electrode can be structured out of the first functional material layer in such a way that a vertical evaluation electrode surface and a vertical deflection electrode surface are formed with a vertical electrode gap therebetween. The first functional material layer can be produced from multiple successively arranged functional material sublayers.

According to one example embodiment of the present invention, a seismic mass of the sensor component can be created by means of a second functional material layer arranged on the first functional material layer. This provides a separate functional layer for the seismic mass so that the mechanical function of the seismic mass and the electrical function of the deflection electrode can be individually optimized layer-by-layer, for example with regard to material selection, doping and/or dimensioning. The first functional material layer and the second functional material layer can, for example, be produced from different materials and/or with different layer thicknesses. In particular, the second functional material layer may have a greater layer thickness, for example a layer thickness that is at least five times or at least ten times as high as a layer thickness of the first functional material layer. The second functional material layer can be arranged on the first functional material layer on a side thereof facing away from the substrate. As a result, in the sensor component, the deflection and evaluation electrodes exposed from the first functional material layer are enclosed by the seismic mass and the substrate. The first functional material layer can further increase the effective mass of the seismic mass in the layer regions of the deflection electrode in which the first functional material layer adjoins the second functional material layer. In particular, it is not necessary to form the deflection electrode from the material of the second functional material layer intended for the seismic mass, so that, for example, no mass reduction in the region of the seismic mass is required for the vertical bar or comb structure proposed above. Furthermore, the provision of a first functional material layer in which the vertical detection arrangement is exposed has the advantage that it optionally has a significantly smaller layer thickness in comparison to the second functional material layer and the vertical electrode surfaces can thus be more easily exposed from the first functional material layer than from the second functional material layer. Thus, when creating vertical trenches by etching processes in semiconductor production steps, it is essential to ensure a suitable aspect ratio. This means that in layers with smaller layer thicknesses, narrower trenches and thus also narrower electrode gaps between opposing vertical electrode surfaces can be produced, which promote a pronounced measurement signal.

According to one example embodiment of the present invention, the first functional material layer can be structured in such a way that at least one evaluation electrode bar with a vertical evaluation electrode surface and/or at least one deflection electrode bar with a vertical deflection electrode surface is exposed from the first functional material layer while forming the vertical electrode gap. This allows a defined detection arrangement with vertical electrode surfaces to be created. If at least one evaluation electrode bar and at least one deflection electrode bar are produced, they can be exposed in pairs at different heights from the first functional material layer. As a result, the evaluation electrode bar and the deflection electrode bar do not run completely parallel to each other, but only in portions, i.e., have a defined vertical offset. This allows the achievable variable overlap during a deflection of the deflection electrode in the finished sensor component to be optimized for opposite deflection directions transverse to the substrate.

According to one example embodiment of the present invention, the auxiliary material layer edges can be formed by at least one sacrificial layer edge and/or by at least one photoresist edge. This allows a vertical contour of the deflection electrode and/or the evaluation electrode to be predefined in a simple and efficient manner. In particular, multiple sacrificial layer edges can also be combined with one another or with an additional photoresist edge in order to achieve a particularly precise definition of the vertical contour. For example, two sacrificial layer edges and one photoresist edge can be formed in different levels of the layer structure. In this case, the auxiliary material layer edges are precisely aligned to one another in the vertical direction in order to make an almost continuous predefinition of the vertical contour possible. This makes it possible to form in particular very even vertical electrode surfaces, which make a linear and uniform measurement signal over the entire deflection distance of the deflection electrode possible. The auxiliary material layer edges can be locally and specifically structured into the auxiliary material layer after the application of an auxiliary material layer and are therefore to be distinguished in particular from marginal edges of the auxiliary material layers, which are present in a lateral edge region of the auxiliary material layers in the layer structure. The sacrificial layer edge can be structured into a sacrificial layer, which is, for example, a dielectric layer made of a silicon compound such as silicon dioxide. The photoresist edge can, for example, be introduced into a photosensitive polymer layer.

According to one example embodiment of the present invention, a first auxiliary material layer edge for predefining a vertical electrode gap, a second auxiliary material layer edge for predefining a vertical evaluation electrode surface, and a third auxiliary material layer edge for predefining a vertical deflection electrode surface can be applied in the successive arrangement of functional material layers and auxiliary material layers. This allows the vertical contours of the deflection and evaluation electrode surfaces to be precisely specified. In particular, two mutually spaced outer first auxiliary material layer edges can be created, which, viewed laterally, enclose two mutually spaced inner second auxiliary material layer edges. This allows two vertical evaluation electrode surfaces to be produced between two vertical deflection electrode surfaces, for example in the form of a vertical evaluation electrode bar.

According to one example embodiment of the present invention, the first auxiliary material layer edge can be produced by a recess in a first sacrificial layer, and the second auxiliary material layer edge can be produced by a sacrificial element of a second sacrificial layer buried in the first functional material layer. This allows in a simple and efficient manner two first sacrificial layer edges to be created on the lateral outer edges of the recess and two second sacrificial layer edges to be created on the lateral outer edges of the sacrificial element, which support the precise creation of two vertical evaluation electrode surfaces and two vertical deflection electrode surfaces. The recess can be created by locally removing sacrificial material in the region of the provided recess after application of the first sacrificial layer. The sacrificial element can be created by locally removing sacrificial material adjacent to a region of the provided sacrificial element after application of the second sacrificial layer. In order to bury the sacrificial element in the first functional material layer, the first functional material layer can be applied in functional material sublayers so that, for example, in succession, a first functional material sublayer is deposited, a second sacrificial layer is deposited and structured, and a second functional material sublayer is then applied.

According to one example embodiment of the present invention, a defined connection region between the first functional material layer and the second functional material layer can be created by means of a structured auxiliary material layer. The connection region may, for example, have a T-shaped cross-section. The connection region may have a greater width than the electrode gap. The connection region may also serve as an etching channel for later sacrificial layer etching and promote etching gas distribution through the sensor component.

According to one example embodiment of the present invention, a planarization step can be carried out before applying an auxiliary material layer provided for forming an auxiliary material layer edge. This allows the auxiliary material layer edge to be aligned particularly precisely with the particularly flat and even surface. This allows very straight vertical electrode surfaces and very narrow electrode gaps to be produced with high accuracy. The planarization can, for example, be carried out down to a level of a buried sacrificial layer element. For example, a structured photoresist layer can then be arranged on the planarized layer in order to form photoresist edges. The planarization step can be carried out, for example, using a chemical-mechanical polishing (CMP) process. It is not necessarily required that the surface directly beneath the auxiliary material layer be planarized. It is also possible, for example, that a functional material sublayer provided beneath the auxiliary material layer is first applied, planarized, and then applied again in order, for example, to compensate for a flow of functional material into a recess of an underlying sacrificial layer with any resulting indentations and to be able to provide a comparatively flat surface for the application of the auxiliary material layer.

According to one example embodiment of the present invention, a carrier structure for mechanically and/or electrically connecting the evaluation electrode can be produced on an auxiliary material layer arranged on the substrate. This makes it possible to achieve a particularly robust connection of the evaluation electrode to the substrate. The buried carrier structure can, for example, be a polysilicon layer. The carrier structure can, for example, be buried in the auxiliary material layer. For producing the buried carrier structure, the auxiliary material layer can be applied in sublayers. The auxiliary material layer may be a sacrificial layer, for example a silicon dioxide layer. The carrier structure can also act as an etch stop during sacrificial layer etching so that a sublayer located between the carrier structure and the substrate is not removed during sacrificial layer etching and a robust connection of the evaluation electrode to the substrate can be achieved.

According to one example embodiment of the present invention, an etch stop structure adjacent to the carrier structure can be created between the substrate and the carrier structure for an etching process structuring the carrier structure. This allows the carrier structure to be divided into multiple mutually isolated regions during an etching process, which makes it possible to place the mutually isolated region at different electrical potentials. The etching process can, for example, be a trench etching process for exposing the vertical electrode surfaces, which is continued up to the etch stop structure. The etch stop structure can, for example, be a dielectric layer, in particular made of a silicon-rich nitride (SiRiN). Due to the mutually isolated electrical regions of the carrier structure, parasitic effects can be avoided in the event of a bending of the substrate or in the event of large deflections of the deflection electrode or a small distance between the deflection electrode and the substrate.

In general, in the context of this application, the words “a/an,” unless expressly defined otherwise, are not to be understood as numerals, but as indefinite articles with the literal meaning of “at least one.”

The present invention allows for various embodiments and is explained in more detail below using exemplary embodiments with the figures.

### BRIEF DESCRIPTION OF THE DRAWINGS

FIG. 1 is a partial schematic view of a microelectromechanical sensor component according to an example embodiment of the present invention in a sectional front view.

FIG. 2-10 show selected method steps of a method for producing a microelectromechanical sensor component according to a first design variant based on a partial sectional front view of the sensor component, according to the present invention.

FIG. 11-14 show selected method steps of a method for producing a microelectromechanical sensor component according to a second design variant based on a partial sectional front view of the sensor component, according to the present invention.

FIG. 15-17 show selected method steps of a method for producing a microelectromechanical sensor component according to a third design variant based on a partial sectional front view of the sensor component, according to the present invention.

FIG. 18-21 show selected method steps of a method for producing a microelectromechanical sensor component according to a fourth design variant based on a partial sectional front view of the sensor component, according to the present invention.

FIG. 22-25 show selected method steps of a method for producing a microelectromechanical sensor component according to a fifth design variant based on a partial sectional front view of the sensor component, according to the present invention.

FIG. 26 is a simplified schematic view of a microelectromechanical inertial sensor having a microelectromechanical sensor component, according to an example embodiment of the present invention.

### DETAILED DESCRIPTION OF EXAMPLE EMBODIMENTS

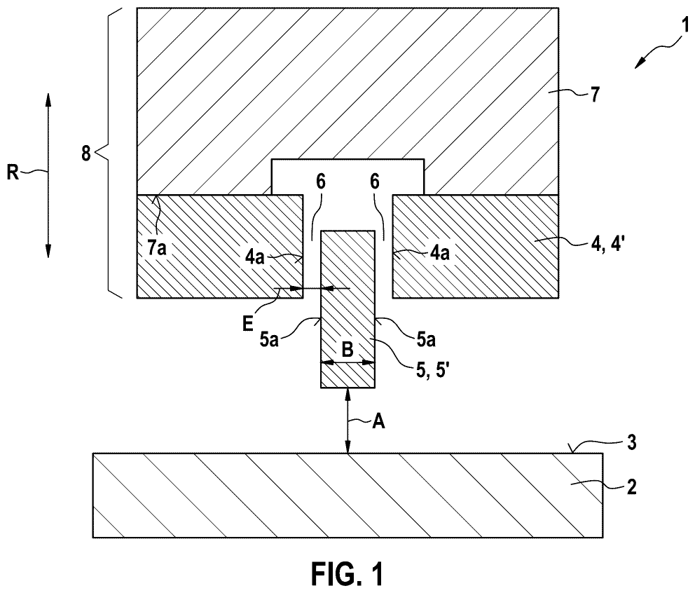

FIG. 1 is a schematic view of a detail of a microelectromechanical sensor component 1 in a sectional front view. According to the described exemplary embodiment, the sensor component 1 is configured for direction-dependent detection of an acceleration or rotation rate by detecting and measuring an out-of-plane deflection of a movable sensor structure 8.

The microelectromechanical sensor component 1 comprises a substrate 2 having a substrate surface 3. A sensor structure 8, which is movable relative to the substrate surface 3 and has a seismic mass 7 and a deflection electrode 4 arranged thereon, is arranged at a distance from the substrate surface 3. The seismic mass 7 can, for example, be movably mounted on a fixed frame of the sensor component 1 via a spring structure (not shown in detail). The movable sensor structure 8 is movable substantially perpendicularly to the substrate surface 3 in a deflection direction R toward and away from the substrate surface 3. In FIG. 1, the movable sensor structure 8 is shown in a rest position, in which there is no acceleration force acting on the sensor component 1.

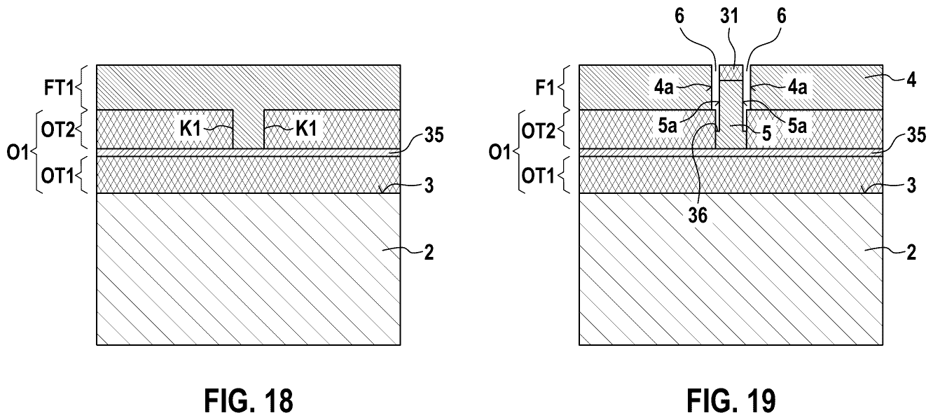

The sensor component 1 further comprises an evaluation electrode 5, which is configured to capacitively detect a deflection of the deflection electrode 4. The evaluation electrode 5 is located at least partially between the substrate surface 3 and the deflection electrode 4 and can be connected to the substrate 2 via a mechanical anchoring (not shown in detail) or can be connected to an additional carrier structure 35 as shown in FIG. 18.

As can be seen in FIG. 1, the evaluation electrode 5 has an evaluation electrode bar 5′ extending substantially perpendicularly to the substrate surface 3 and designed as an electrode finger, on which two mutually opposing vertical evaluation electrode surfaces 5a are formed. Furthermore, the deflection electrode 4 has two deflection electrode bars 4′ designed as electrode blocks, which point from the seismic mass 7 in the direction of the substrate surface 3. According to the illustration, the deflection electrode bars 4′ have two vertical deflection electrode surfaces 4a, which run parallel to the vertical evaluation electrode surfaces 5a in portions. In this case, a vertical electrode gap 6 is present in each case between a vertical deflection electrode surface 4a and a vertical evaluation electrode surface 5a. In other words, the vertical evaluation electrode bar 5′ is immersed into an intermediate space between the deflection electrode bars 4′ in portions, it being possible for the immersion depth to increase or decrease upon deflection of the movable sensor structure 8. In this case, a spatial overlap of the vertical evaluation electrode surfaces 5a and the vertical deflection electrode surfaces 4a changes in a vertical direction, i.e., increases when the movable sensor structure 8 is deflected in the direction of the substrate 2 and decreases when the movable sensor structure 8 is deflected in the opposite direction. Due to the variable overlap, a linear capacitive measurement signal is obtainable at the evaluation electrode 5, which is representative of a deflection of the movable sensor structure 8. In the rest position of the movable sensor structure 8 shown in FIG. 1, the evaluation electrode bar 5′ extends further in the direction of the substrate surface 3 than the deflection electrode bars 4′, and the deflection electrode bars 4′ extend further in an opposite direction than the evaluation electrode bars 5′. This preset vertical offset achieves favorable wide-area coverage of displacements of the movable sensor structure 8 toward and away from the substrate surface 3.

With the proposed design of the sensor component 1, a vertical detection arrangement is obtainable, with which a consistent measurement sensitivity can be ensured even in the case of stress-dependent or environmentally dependent mechanical bending of components of the sensor component 1. In addition, in contrast to a measurement principle based on changes in distance between horizontal electrode surfaces, a detection based on changes in overlap between vertical electrode surfaces provides a linear measurement signal for out-of-plane deflections of the movable sensor structure 8. Furthermore, the proposed vertical detection arrangement allows a large degree of flexibility in the structural design of the sensor component 1 since mechanical bending effects have a significantly reduced influence on the measurement accuracy of the sensor component 1.

As schematically indicated in FIG. 1, an extension E of the vertical electrode gap 6 between the deflection electrode surfaces 4a and the evaluation electrode surfaces 5a can be dimensioned such that, in the shown rest position of the deflection electrode 4, it is at most half as large as a distance A between the substrate surface 3 and the deflection electrode 4. In particular, the extension E may be a maximum of one quarter of the distance A. Accordingly, a vertical detection structure with particularly narrow electrode gaps 6 is provided, which can promote strong capacitive measurement signals. As can be further seen in FIG. 1, the extension E can furthermore be at most half as large as a width B of the evaluation electrode bar 5′ parallel to the substrate surface 3. This provides a robust, yet sensitive vertical detection structure. As can be seen schematically in FIG. 1, the vertical evaluation electrode surfaces 5a and the vertical deflection electrode surfaces 4a have a straight, flat course along their vertical extension, whereby a precise linear capacitive measurement signal is obtainable, in particular over the entire maximum possible displacement path of the deflection electrode 4.

Although the image section shown in FIG. 1 only representatively shows one evaluation electrode bar 5′ and two deflection electrode bars 4′, the sensor component 1 can have a higher number of evaluation electrode bars 5′ and deflection electrode bars 4′, which are arranged alternately and interlock vertically in a comb-like manner to form a vertical comb structure. With such a vertical comb structure, reliable and precise deflection detection over a wide range of the movable sensor structure 8 is possible.

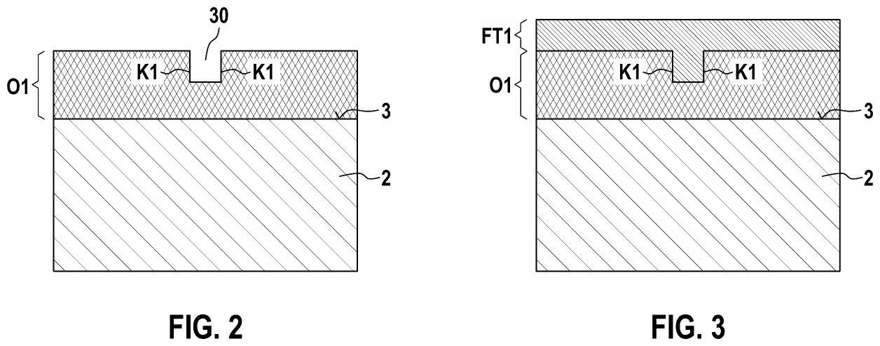

FIG. 2 to 10 show selected method steps of a method for producing a microelectromechanical sensor component 1 according to a first design variant, using sectional views of the sensor component 1, which are explained in more detail below. In this case, the method steps show, by way of example, a production of the component region of the sensor component 1 shown in FIG. 1, the method steps being usable analogously for the production of further component regions with additional evaluation electrode bars 5′ and deflection electrode bars 4′.

According to the state shown in FIG. 2, a first sacrificial layer O1 was deposited on a substrate 2 having a substrate surface 3, for example on a silicon wafer. The first sacrificial layer O1 can, for example, be a silicon dioxide layer.

Furthermore, a recess 30 was etched into the first sacrificial layer O1. The recess 30 forms two first sacrificial layer edges Kl, each of which predefines the subsequent electrode gap 6 between the vertical deflection electrode surface 4′ and the vertical evaluation electrode surface 5′. In particular, a plasma etching method can be provided for producing the recess 30. The recess 30 is in particular created in such a way that it has substantially vertical side walls, for example with an angle between 75° and 90°. The recess 30 can in particular be created as an elongate trench.

According to the state shown in FIG. 3, a first functional material sublayer FT1 was deposited, which together with a later applied functional material sublayer FT2 forms a first functional material layer F1. The first functional material sublayer FT1 can be a polysilicon layer. A layer thickness of the deposition of the first functional material sublayer FT1 can in particular be at least half as large as a width of the recess 30 parallel to the substrate surface 3, in order to ensure that the recess 30 is filled as completely as possible.

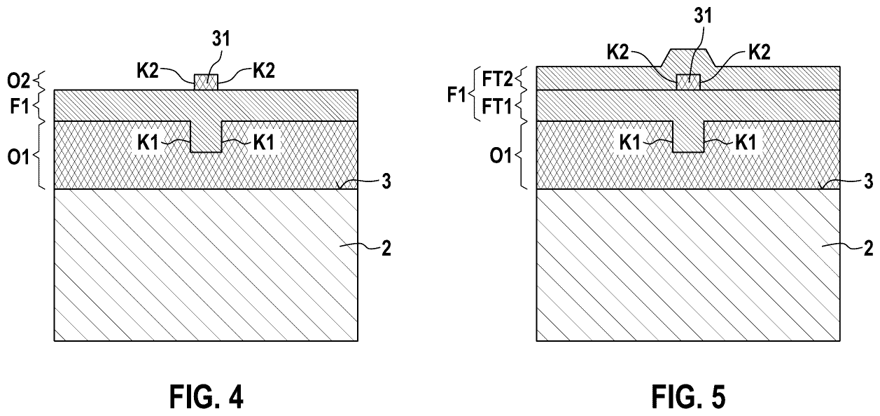

According to the state shown in FIG. 4, a second sacrificial layer O2 was deposited and structured in such a way that a laterally limited local sacrificial element 31 remains on the first functional material sublayer FT1. The lateral limitation of the sacrificial element 31 forms two second sacrificial layer edges K2, which predefine a later partial contour of the vertical evaluation electrode surfaces 5′. Viewed laterally, the second sacrificial layer edges K2 are located within a region predefined vertically by the first sacrificial layer edges K1.

The second sacrificial layer O2 can, for example, be a silicon dioxide layer. In particular, a plasma etching method can be provided for producing the sacrificial element 31. The sacrificial element 31 is in particular produced in such a way that it has substantially vertical side walls, for example with an angle between 75° and 90°. The sacrificial element 31 can in particular be produced as an elongate web.

According to the state shown in FIG. 5, a second functional material sublayer FT2 was deposited so that, together with the first functional material sublayer FT1, the first functional material layer F1 is formed, in which the sacrificial element 31 is buried. The second functional material sublayer FT2 can also be a polysilicon layer and in particular have the same material properties as the first functional material sublayer FT1.

According to the state shown in FIG. 6, a photoresist layer L1 was applied to the functional material layer F1, photoresist edges K3 being formed in the photoresist layer L1 in such a way that they are substantially aligned with a course of the first sacrificial layer edges K1, i.e., are arranged vertically one above the other. The photoresist edges K3 define a boundary for a subsequent etching method and thereby determine a course of the vertical deflection electrode surfaces 4a exposed by the etching method.

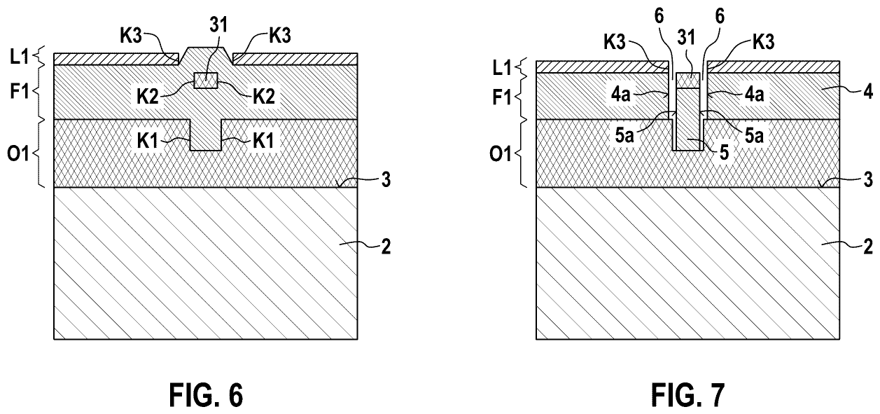

FIG. 7 shows the state of the component region after the etching method has been carried out, a trench etching method having been chosen as the etching method in this case, in order to allow for selective removal of the polysilicon-based functional material of the functional material layer F1 selectively to the silicon dioxide-based sacrificial layer material. The first sacrificial layer edges K1, the second sacrificial layer edges K2 and the photoresist edges K3 allow for precise spatial control of the etching process to form even vertical deflection electrode surfaces 4a and evaluation electrode surfaces 5a. In particular, in this case, substantially vertical electrode surfaces are produced, which have an angle of 85° to 95°.

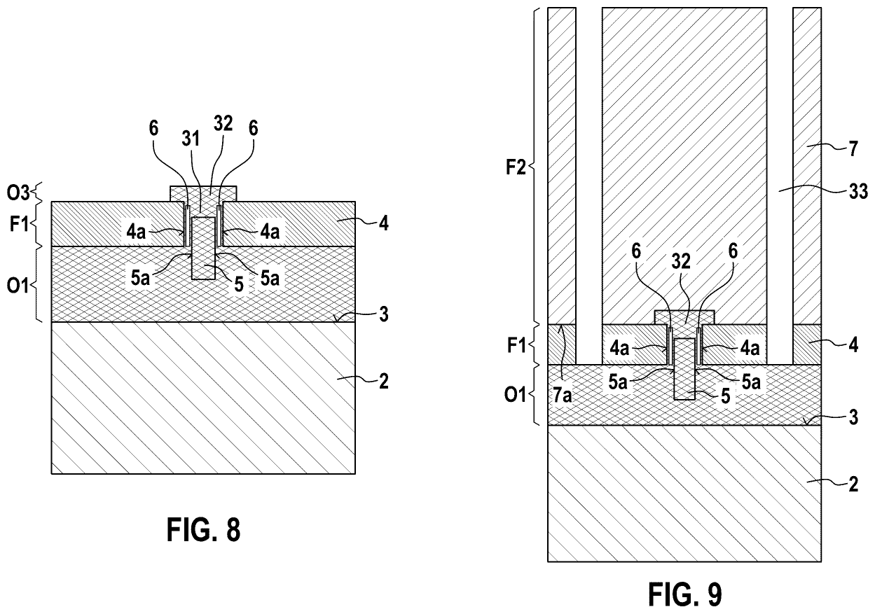

FIG. 8 shows how a third sacrificial layer O3 was applied and structured in order to produce a defined connection region 32 between the first functional layer F1 and the second functional layer F2 to be applied subsequently. The connection region 32 may, for example, have a T-shaped cross-section and be wider than the electrode gaps 6. The connection region 32 can thus additionally serve as an etching channel for a subsequent sacrificial layer etching and thus promote etching gas distribution during the exposure of the functional structures of the sensor component 1.

According to the state shown in FIG. 9, a second functional material layer F2 was deposited and structured. The second functional material layer F2 forms a seismic mass 7 of the sensor component 1, to which the deflection electrode 4, which is exposed from the first functional material layer F1, is connected. The second functional material layer F2 can, for example, be a polysilicon layer. The second functional material layer F2 can in principle have material properties that differ from the material properties of the first functional material layer F1, for example a different doping. At least the second functional material layer F2 has a significantly higher layer thickness than the first functional material layer F1, in order to be able to provide a high mass for interaction with acceleration forces. For example, a layer thickness of the second functional material layer F2 can be at least five times or at least ten times as large as a layer thickness of the first functional material layer F1. By structuring the second functional material layer F2, etching accesses 33 can be created for a subsequent sacrificial layer etching for the removal of the sacrificial layers O1, O2, O3. The structuring of the second functional material layer F2 can be carried out, for example, by means of a trench etching method. By means of the trench etching method, the etching accesses 33 can also be extended into the layer region of the first functional material layer F1 in order to achieve favorable access to the sacrificial layers O1, O2, O3. Since the cavities on the vertical detection arrangement, for example the electrode gaps 6 and the connection regions 32, can be used as additional etching channels, fewer etching accesses 33 can in principle be created in the seismic mass 7 than has previously been the case in practice.

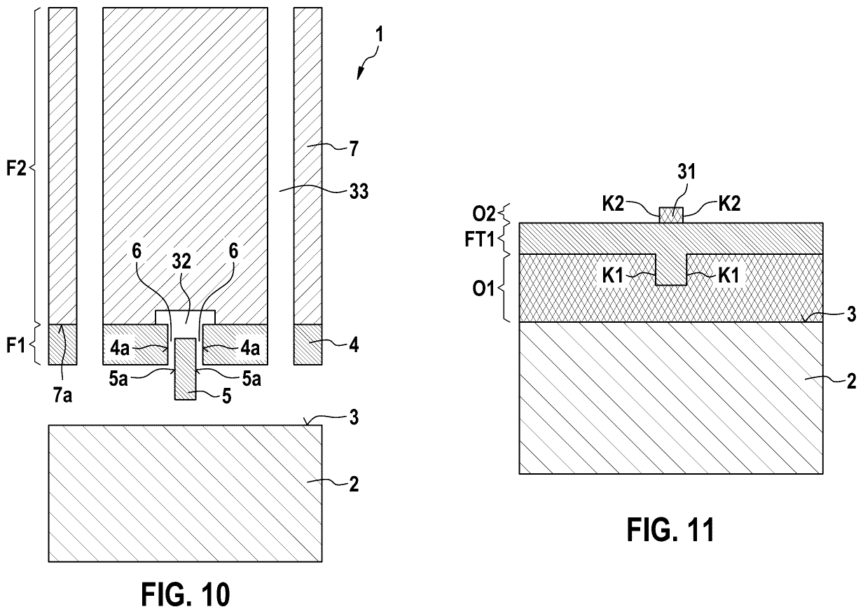

FIG. 10 shows how the sacrificial layers O1, O2, O3 were removed by means of a sacrificial layer etching and how the deflection electrode 4 and the evaluation electrode 5 were thereby exposed. As a result, the deflection electrode 4 is movable together with the seismic mass 7 relative to the evaluation electrode 5, and a deflection of the deflection electrode 4 can be detected capacitively with high accuracy and consistent sensitivity by means of the vertical detection arrangement. The sacrificial layer etching can be carried out, for example, using an Hf-containing etching method, in particular in the gas phase.

FIG. 11 to 14 show selected method steps of a method for producing a microelectromechanical sensor component 1 according to a second design variant. The method can basically correspond to the above-described first design variant in most of the method steps and deviate from the first design variant only in the optional additional or alternative method steps described below. In FIG. 11, a state analogous to the state shown in FIG. 4 is shown, in which the sacrificial layer element 31 was produced.

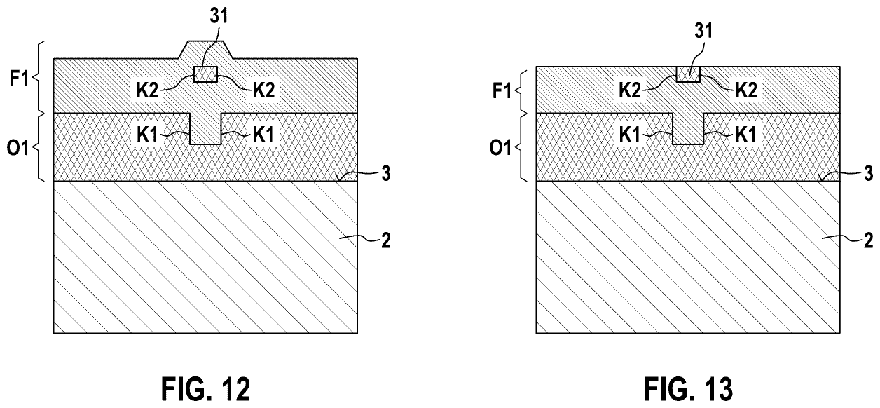

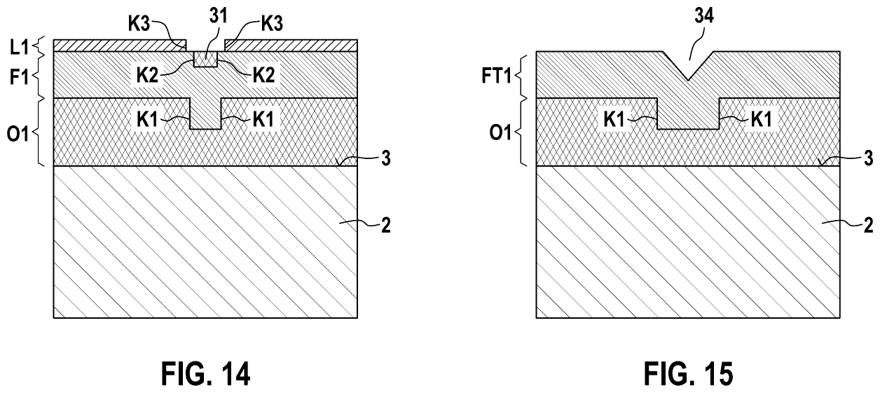

In FIG. 12, a state analogous to the state shown in FIG. 5 is shown, in which the sacrificial layer element 31 was buried in the first functional material layer F1 by applying the second functional material sublayer FT2. FIG. 13 shows that a planarization step was subsequently carried out, for example by means of a chemical-mechanical polishing (CMP) process. The planarization can in particular be carried out up to a level of the sacrificial layer element 31. As a result, as shown in FIG. 14, a very precise alignment of the resist layer edges K3 can subsequently be achieved when the photoresist layer L1 is applied to the flat surface, so that particularly narrow electrode gaps 6 can be created.

FIG. 15 to 17 show selected method steps of a method for producing a microelectromechanical sensor component 1 according to a third design variant. The method can basically correspond to the above-described first design variant in most of the method steps and deviate from the first design variant only in the optional additional or alternative method steps described below.

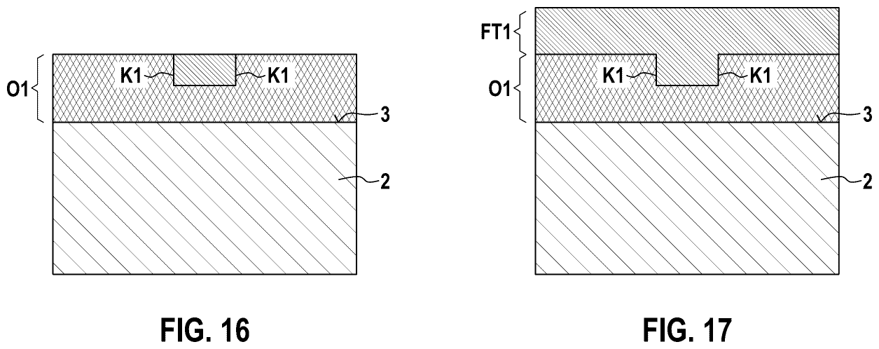

In FIG. 15, a state analogous to the state shown in FIG. 2 is shown, it being schematically illustrated that the material of the first functional material sublayer FT1 flowing into the recess 30 can result in a local indentation 34. The local indentation 34 may impair precise structuring of a subsequently applied second sacrificial layer O2 for producing the sacrificial element 31. Therefore, after the application of the first functional material sublayer FT1 as shown in FIG. 16, a planarization step can be carried out, for example by means of a CMP process, in order to again deposit a first functional material sublayer FT1 and then to be able to apply the second sacrificial layer O2, for producing the sacrificial element 31, on a comparatively flat surface as shown in FIG. 17.

FIG. 18 to 21 show selected method steps of a method for producing a microelectromechanical sensor component 1 according to a fourth design variant. The method can basically correspond to the above-described first design variant in most of the method steps and deviate from the first design variant only in the optional additional or alternative method steps described below.

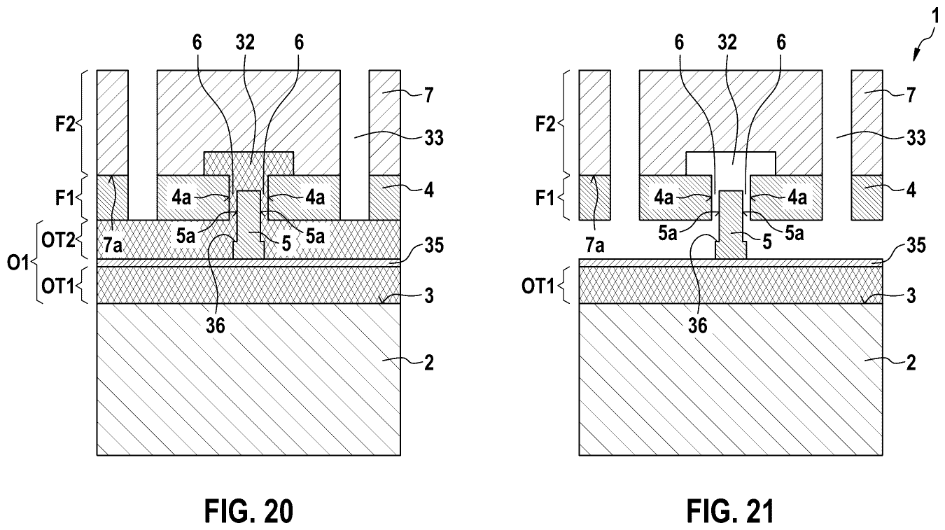

In FIG. 18, a state analogous to the state shown in FIG. 2 is shown, a buried carrier structure 35 being provided in the first sacrificial layer O1 for the mechanical and/or electrical connection of the evaluation electrode 5. An electrical connection can, for example, be used to apply and/or discharge electrical signals and potentials. The buried carrier structure 35 may, for example, be a polysilicon layer. In order to produce the buried carrier structure 35, the first sacrificial layer O1 can be applied in two sacrificial sublayers OT1 and OT2, as indicated in FIG. 18. In FIG. 19, it can be seen that the trench etching process for producing the electrode gaps 6 is time-controlled in such a way that it stops before reaching the carrier structure 35. In this way, shoulders 36 can be introduced into the evaluation electrode 5 and a robust widened base for the molded evaluation electrode bar 5′ can be obtained. FIG. 20 shows, analogously to the state shown in FIG. 9, that a connection region 32 with a T-shaped cross-section and the second functional material layer F2 have been created. According to FIG. 21, the sacrificial layer etching was carried out for the removal of the sacrificial layers O1, O2, O3, the buried carrier structure 35 acting as an etch stop, so that only the second sacrificial sublayer OT2 is removed from the first sacrificial layer O1. This allows a very robust connection of the carrier structure 35 to the substrate 2 to be achieved.

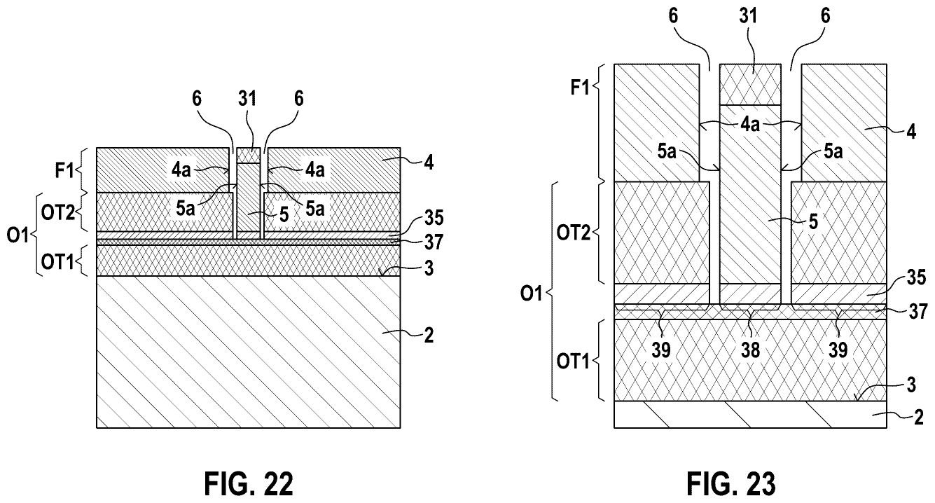

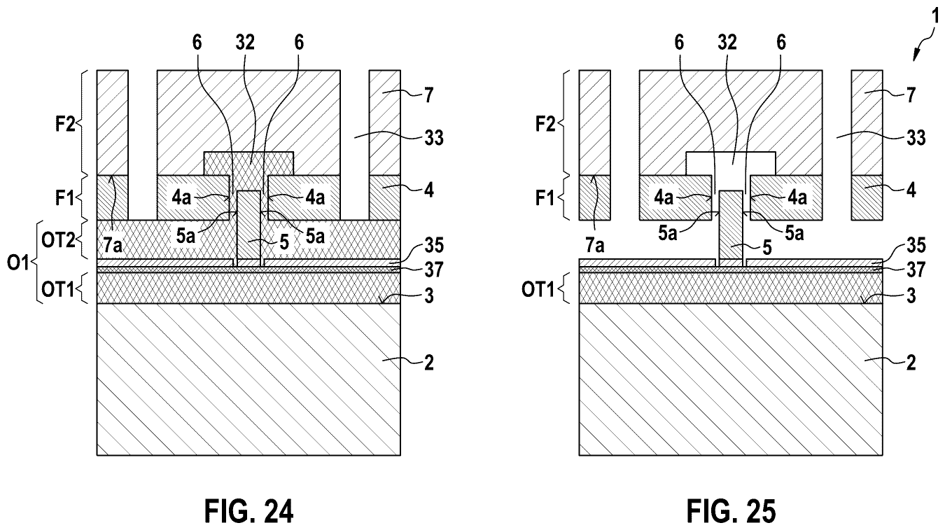

FIG. 22 to 25 show selected method steps of a method for producing a microelectromechanical sensor component 1 according to a fifth design variant. In most method steps, the method can basically correspond to the first design variant described above and, in addition, to the fourth design variant described above, and deviate from the first and fourth design variants only in the optional additional or alternative method steps described below. As can be seen in FIG. 22 to 25, an etch stop structure 37 adjacent to the carrier structure 35 is arranged between the substrate and the carrier structure 35. The etch stop structure 37 may be a dielectric layer, in particular made of a silicon-rich nitride (SiRiN). As can be seen in FIG. 23, the etch stop structure 37 can not only form an etch stop for a later sacrificial layer etching but also stop a trench etching process that can be carried out up to the etch stop structure 37. As a result, as shown in FIG. 23, an electrical isolation of a first region 38 of the carrier structure 35 below the evaluation electrode bar 5′ from adjacent second regions 39 can be achieved so that the mutually isolated regions 38, 39 of the carrier structure 35 can be placed at different electrical potentials. It may be advantageous in this case to set the second regions 39 to the side of the evaluation electrode bar 5′ to the same potential in order to avoid parasitic effects in the event of a bending of the substrate 2. The fifth design variant can be advantageous, for example, if a small distance is provided between the carrier structure 35 and the deflection electrode 4 or if pronounced bending of the substrate 2 or large deflections of the deflection electrode 4 are expected.

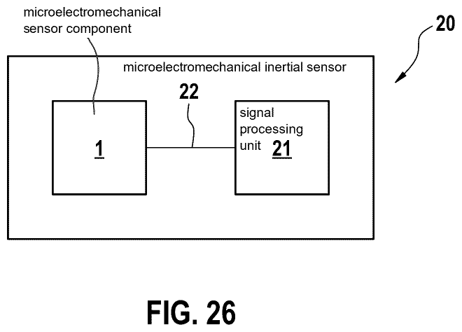

FIG. 26 is a schematic view of a microelectromechanical inertial sensor 20 having a microelectromechanical sensor component 1 according to one of the features described above, which is connected via a signal connection 22 to a signal processing unit 21, for example designed as an ASIC, for applying and processing signals of the microelectromechanical sensor component 1. The microelectromechanical inertial sensor 20 can be designed, for example, as an acceleration sensor for detecting a translational acceleration and/or as a rotation rate sensor for detecting a rotational acceleration. The proposed vertical detection arrangement of the microelectromechanical sensor component 1 provides a robust and reliable inertial sensor 20 with a high, consistent measurement sensitivity.

1-18. (canceled)

19. A microelectromechanical sensor component, comprising:
a substrate with a substrate surface;
a deflection electrode movable substantially perpendicularly to the substrate surface; and
an evaluation electrode configured to capacitively detect a deflection of the deflection electrode;
wherein the evaluation electrode has a vertical evaluation electrode surface which is aligned substantially perpendicularly to the substrate surface and extends at least in portions parallel to a vertical deflection electrode surface of the deflection electrode while forming a vertical electrode gap between the vertical deflection electrode surface and the vertical evaluation electrode surface.

20. The microelectromechanical sensor component according to claim 19, wherein: (i) the evaluation electrode has an evaluation electrode bar which extends substantially perpendicularly to the substrate surface and on which the vertical evaluation electrode surface is formed, and/or (ii) the deflection electrode has a deflection electrode bar which extends predominantly perpendicularly to the substrate surface and on which the vertical deflection electrode surface is formed.

21. The microelectromechanical sensor component according to claim 20, wherein the microelectromechanical sensor component has a plurality of evaluation electrode bars and a plurality of deflection electrode bars, which engage vertically in a comb-like manner.

22. The microelectromechanical sensor component according to claim 19, further comprising:
a seismic mass having a mass surface which faces the substrate and on which the deflection electrode is arranged.

23. The microelectromechanical sensor component according to claim 19, wherein an extension of the vertical electrode gap between the deflection electrode surface and the evaluation electrode surface is at most half as large as a distance between the substrate surface and the deflection electrode in a rest position of the deflection electrode.

24. The microelectromechanical sensor component according to claim 19, wherein the vertical evaluation electrode surface and/or the vertical deflection electrode surface are predominantly flat.

25. A microelectromechanical inertial sensor, comprising:
a microelectromechanical sensor component; and
a signal processing unit configured to apply and/or process signals of the microelectromechanical sensor component;
wherein the microelectrical sensor component includes:
a substrate with a substrate surface,
a deflection electrode movable substantially perpendicularly to the substrate surface, and
an evaluation electrode configured to capacitively detect a deflection of the deflection electrode,
wherein the evaluation electrode has a vertical evaluation electrode surface which is aligned substantially perpendicularly to the substrate surface and extends at least in portions parallel to a vertical deflection electrode surface of the deflection electrode while forming a vertical electrode gap between the vertical deflection electrode surface and the vertical evaluation electrode surface.

26. A method for producing a microelectromechanical sensor component, the microelectromechanal sensor component including:
a substrate with a substrate surface,
a deflection electrode movable substantially perpendicularly to the substrate surface, and
an evaluation electrode configured to capacitively detect a deflection of the deflection electrode,
wherein the evaluation electrode has a vertical evaluation electrode surface which is aligned substantially perpendicularly to the substrate surface and extends at least in portions parallel to a vertical deflection electrode surface of the deflection electrode while forming a vertical electrode gap between the vertical deflection electrode surface and the vertical evaluation electrode surface;
the method comprising the following steps:
sequentially arranging and layer-by-layer structuring of functional material layers and auxiliary material layers, wherein a course of the vertical evaluation electrode surface, the vertical deflection electrode surface and the vertical electrode gap is predefined by edges of the auxiliary material layer.

27. The method according to claim 26, wherein the evaluation electrode and the deflection electrode of the sensor component are produced using a first functional material layer of the functional material layers.

28. The method according to claim 27, wherein a seismic mass of the sensor component is created using a second functional material layer of the functional material layers, the second functional material layer being arranged on the first functional material layer.

29. The method according to claim 27, wherein the first functional material layer is structured in such a way that at least one evaluation electrode bar with a vertical evaluation electrode surface and/or at least one deflection electrode bar with a vertical deflection electrode surface, is exposed from the first functional material layer while forming the vertical electrode gap.

30. The method according to claim 26, wherein the edges of the auxiliary material layer are formed by at least one sacrificial layer edge and/or by at least one photoresist edge.

31. The method according to claim 26, wherein an edge of the first auxiliary material layer of the auxiliary material layers for predefining a vertical electrode gap, an edge of the second auxiliary material layer of the auxiliary material layers for predefining a vertical evaluation electrode surface, and an edge of a third auxiliary material layer of the auxiliary material layers for predefining a vertical deflection electrode surface are applied in a successive arrangement of the functional material layers and the auxiliary material layers.

32. The method according to claim 31, wherein an edge of the first auxiliary material layer edge is produced by a recess in a first sacrificial layer, and an edge of the second auxiliary material layer is produced by a sacrificial element of a second sacrificial layer buried in a first functional material layer of the functional material layers.

33. The method according to claim 26, wherein a defined connection region between a first functional material layer of the functional material layers and a second functional material layer of the functional layer materials is produced by structuring an auxiliary material layer of the auxiliary material layers.

34. The method according to claim 26, wherein a planarization step is carried out before application of an auxiliary material layer of the auxiliary material layers, the planarization step forming an edge of the auxiliary material layer.

35. The method according to claim 26, wherein a carrier structure for mechanically and/or electrically connecting the evaluation electrode is produced on an auxiliary material layer of the auxiliary material layers arranged on the substrate.

36. The method according to claim 35, wherein an etch stop structure adjacent to a carrier structure is produced between the substrate and the carrier structure for an etching process structuring the carrier structure.
